(19) United States
(12) Patent Application Publication
(10) Pub. No.: US 2014/0314107 A1
(43) Pub. Date: Oct. 23, 2014

(54) External Cavity Wideband Tunable Laser with Dual Laser Gain Media Coupled by a Polarization Beam Combiner

(71) Applicant: GP PHOTONICS INC, Tianjin (CN)

(72) Inventor: Peiliang Gao, Tianjin (CN)

(73) Assignee: GP PHOTONICS INC, Tianjin (CN)

(21) Appl. No.: 13/975,040

(22) Filed: Aug. 23, 2013

Related U.S. Application Data
(63) Continuation of application No. PCT/CN2011/078962, filed on Aug. 26, 2011.

(30) Foreign Application Priority Data
Aug. 19, 2011 (CN) 2011102384017

(51) Int. Cl. H01S 5/14

(52) U.S. Cl. CPC H01S 5/143
USPC 372/20

(57) ABSTRACT

The invention relates to an external cavity wideband tunable laser with dual laser gain media coupled by a polarization beam combiner. The laser comprises a first laser gain medium, a first laser cavity end mirror arranged on the first laser gain medium, a first intracavity collimating lens, an active optical phase modulator, a tunable acousto-optic filter, an intracavity reflection mirror, an etalon and a total reflection mirror which are arranged on the opposite side of the tunable acousto-optic filter from the intracavity reflection mirror inside a laser cavity. The laser further comprises a second laser gain medium, a second laser cavity end mirror arranged on the second laser gain medium, a second intracavity collimating lens, a passive polarization rotator, and a polarization beam combiner for coupling the output light beams emitted from the first laser gain medium and the second laser gain medium, a radio frequency signal source, pumping sources for the two laser gain media, an active optical phase modulator drive source and a laser drive control circuit. The invention can significantly expand the output spectrum range of a single tunable laser to cover C and L band. The laser has reliable performance with stable output and compact size, low cost for volume production and easy installation.

### CROSS-REFERENCE TO RELATED APPLICATION

The application is a continuation of PCT/CN2011/1078962 (filed on Aug. 26, 2011), which claims priority of Chinese patent application 201110238401.7 (filed on Aug. 19, 2011), the contents of which are incorporated herein by reference, as if fully set forth herein.

### FIELD OF THE INVENTION

The invention belongs to the field of photonics, and in particular relates to an external cavity wideband tunable laser with dual laser gain media coupled by a polarization beam combiner.

### BACKGROUND OF THE INVENTION

Some tuning technologies described below are mainly used in external cavity tunable lasers. First, tuning is carried out by using a precision stepping motor to drive a grating to rotate, and this technology has the following shortcomings: 1), there are high requirements on precision and repeatability of the stepping motor in achieving optical frequency precision tuning, thus the cost is high; 2), the purpose of miniaturization is hardly achieved due to the stepping motor used; and 3), the working stability is poor under a harsh working environment, in particular, prone to various mechanical vibrations. Because of these problems, the tunable laser using this technology is only suitable for use under a laboratory working environment. Second, tuning is carried out based upon the temperature-based shift of the optical frequency of grating or other optical filtering devices in laser resonant cavity, such as an etalon. This tuning technology has high tuning precision and relatively narrow spectrum bandwidth of output light, but low tuning speed. This shortcoming becomes noticeable especially in the case that wide spectral range tuning is needed. For example: if the temperature shift coefficient of an optical filtering device is 0.2 nanometers/degree, the desired spectrum tuning range and temperature adjustment range are 80 nanometers and 400 degrees respectively, which is impracticable in practical application. Third, tuning is carried out by Micro Electronic Mechanical System (MEMS). This technology has a main shortcoming that the working stability is very poor under a harsh working environment, in particular, prone to various mechanical vibrations. Fourth, tuning is carried out by a tunable acousto-optic filter. This technology has the advantages of high tuning speed, no mechanical movement component and small size, but low tuning precision and relatively wide filtering bandwidth. Therefore, the tunable laser using this technology is only suitable for applications in which the requirement of tuning precision and the output bandwidth are not high. Finally, the tunable lasers using a single laser gain medium can hardly cove both the C and L bands.

To sum up, the existing technologies cannot satisfy a variety of applications of the tunable lasers in which miniaturization, fast tuning within a wide spectrum range, narrowband laser output and long-term stable working under a harsh environment are required, especially for applications in fiber optical communication filed.

### BRIEF DESCRIPTION OF THE DRAWINGS

FIG. 1 is a schematic diagram of an existing conventional tunable acousto-optic filter;

FIG. 2 is a schematic diagram of an existing tunable acousto-optic filter that implements frequency drift compensation;

FIG. 3-1 is a wave vector relation view of incident beam of the first diffraction, acoustic wave field and diffracted light beam in the acousto-optic crystal;

FIG. 3-2 is a wave vector relation view of incident beam of the second diffraction, acoustic wave field and diffracted light beam in the acousto-optic crystal;

FIG. 4 is a schematic drawing of an external cavity tunable laser using a tunable acousto-optic filter and a single etalon:

FIG. 5 is a schematic diagram illustrating the laser gain curve of C spectral band;

FIG. 6 is a schematic diagram illustrating the laser gain curve of L spectral band;

FIG. 7 is an output spectrum diagram of a laser gain medium with 50 GHz optical frequency interval;

FIG. 8 is a schematic drawing of the invention;

FIG. 9 is an output spectrum diagram of the tunable laser with the optical frequency covering C and L spectral bands and with 50 GHz free spectrum range;

FIG. 10 is a functional block diagram of the laser drive control circuit of the invention.

### DETAILED DESCRIPTION OF THE INVENTION

It is an objective of the invention to overcome the shortcomings in the prior art and to provide a polarization-coupled dual-gain medium external cavity bandwidth tunable laser, which is stable and reliable in performance, small in size, low in cost and easy in installation and production.

The technical scheme below is adopted by the invention for solving the technical problems in the prior art:

An external cavity wideband tunable laser with dual laser gain media coupled by a polarization beam combiner comprising: a first laser gain medium, a first laser cavity end mirror arranged on the first laser gain medium, a first intracavity collimating lens for collimating the light beam emitted from the first laser gain medium, an active optical phase modulator, a tunable acousto-optic filter, an intracavity reflection mirror, which are all arranged sequentially, an etalon and a total reflection mirror, which are arranged on the opposite side of the tunable acousto-optic filter from the intracavity reflection mirror, the laser further comprises:

a second laser gain medium, a second laser cavity end mirror arranged on the second laser gain medium, a second intracavity collimating lens for collimating the light beam emitted from the second laser gain medium, the optical axes of second laser gain medium and the second intracavity collimating lens arranged in vertical direction to the optical axes of the first laser gain medium and the first intracavity collimating lens,

a passive polarization rotator arranged behind the first intracavity collimating lens to rotate the polarization direction by 90 degrees of the light beam outputted from the first intracavity collimating lens, and a polarization beam combiner aligned with an angle of 45 degrees with respect to the output light beams of the first intracavity collimating lens and the passive polarization rotator to pass the light beam from the first intracavity collimating lens and to reflect the light beam from the second intracavity collimating lens,

an active polarization rotator arranged on the output light path of the laser and used for rotating the polarization state of the output light beam from the second laser gain medium by 90 degrees so that the polarization state of the output light beam is the same as that of the output light beam from the first laser gain medium,

a radio frequency signal source for providing radio frequency energy for the tunable acousto-optic filter and for adjusting the oscillation wavelength of the laser resonant cavity by changing RF frequency;

pumping sources for the two laser gain media, an active optical phase modulator drive source, an active polarization rotator drive source and a laser drive control circuit.

Further, the gain spectra of the first laser gain medium and the second laser gain medium are C band and L band respectively.

Further, the first laser cavity end mirror is a total reflection mirror or a partial reflection mirror within the C band range, and the second laser cavity end mirror is a total reflection mirror or a partial reflection mirror within the L band range.

Further, the intracavity total reflection mirror has approximately 100% reflectivity within the C band and the L band, and is one of the following types of reflective mirrors: plane mirror, convex mirror and concave mirror.

Further, the spectrum range of the etalon is more than or equal to a spectral band ranging from 186.15 THz to 196.10 THz, and the etalon has a free spectrum range of 50 GHz and high finesse; the spectrum range of the active optical phase modulator is more than or equal to a spectral band ranging from 186.15 THz to 196.10 THz.

Further, the active polarization rotator is one of the following types: electro-optic rotator, or magneto-optic rotator, or liquid crystal rotator, or acousto-optic rotator, or rotators based on other forms of physical optical effect, or a combination of the aforementioned rotators, and the active light rotator has a spectrum range equal to or more than 186.15 THz-196.10 THz.

Further, the tunable acousto-optic filter is a narrow band optical filter and has a spectrum range equal to or more than a spectral band ranging from 186.15 THz to 196.10 THz, and the FWHM of the filter spectrum of the tunable acousto-optic filter is not more than twice the free spectrum range of the etalon.

Further, the tunable acousto-optic filter comprises an acousto-optic crystal and an acoustic wave transducer bonded to the acousto-optic crystal, and the acousto-optic crystal is TeO₂.

Further, the active optical phase modulator is one of the following types: electro-optic phase modulator, or magneto-optic phase modulator, or liquid crystal phase modulator, or acousto-optic phase modulator, or phase modulators based on other forms of physical optical effect, or a combination of the aforementioned phase modulators, and the active optical phase modulator has a spectrum range equal to or more than 186.15 THz-196.10 THz.

Further, the laser drive control circuit comprises a digital signal processor, five digital-to-analog conversion modules, and the digital signal processor is used for controlling the first and second laser pumping sources, the active optical phase modulator drive source, the radio frequency signal source and the active polarization rotator drive source respectively through the five digital-to-analog conversion modules.

The invention has the advantages and positive effects that:

1. C band laser gain medium and L band laser gain medium are coupled by a polarization beam combiner to significantly expand the output spectrum range of a single tunable laser.

2 A tunable narrowband acousto-optic fitter with a single crystal and a single acousto-optic transducer is used in the laser cavity with frequency shift compensation, and fast tuning within C and L band can be achieved by an active optical phase modulator and by changing the RF frequency applied to the tunable narrowband acousto-optic filter. The etalon with 50 GHz free spectrum range and high finesse is used for further compression of output spectrum bandwidth in the laser cavity, and laser output can be regulated to meet the requirement of the international standards for fiber optical telecommunication.

3. The narrow band output within a wide spectrum range are realized by the combination of the narrowband acousto-optic filter, the high finesse etalon and two laser gain media, i.e. C band laser gain medium and L band laser gain medium, which are coupled by a polarization beam combiner. The invention provides a method to build a tunable laser with no mechanical moving component, fast tuning within a wideband spectrum range, stable and narrowband output under an extreme working environment, low cost for volume production, compact and easy installation. Furthermore, the invention has a variety of applications in optical test, fiber optical communication, biology, medical instrument, fiber sensor network and other fields.

Further detailed description is made below to the embodiments of the invention with reference to the drawings.

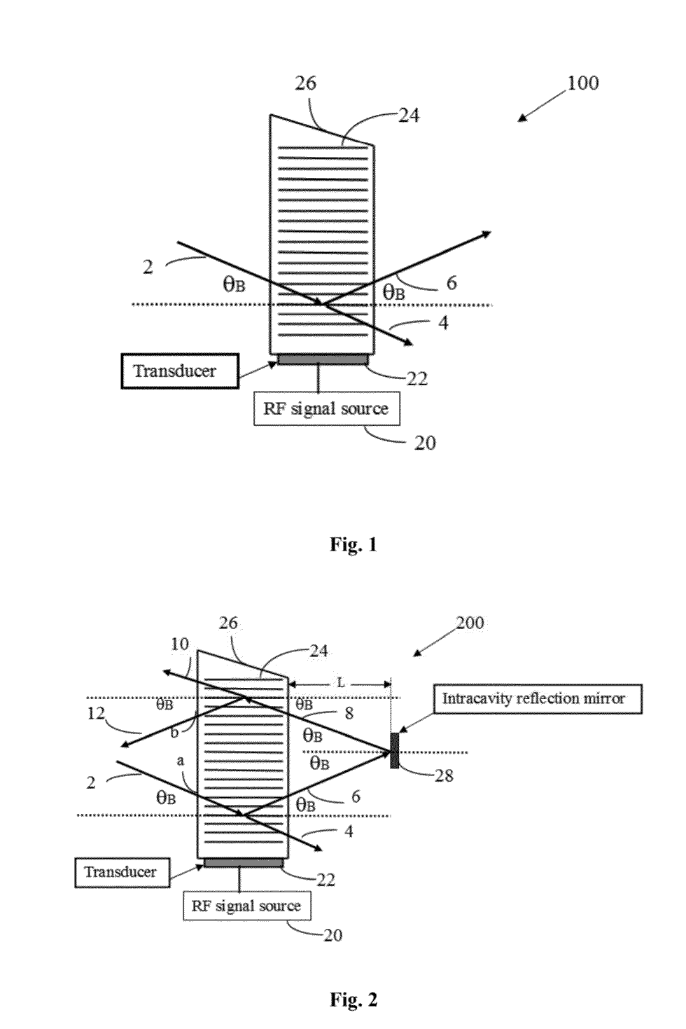

FIG. 1 illustrates a conventional tunable acousto-optic filter 100. The tunable acousto-optic filter 100 comprises a transducer 22, a radio frequency signal source 20 and an acousto-optic crystal 26, the transducer 20 is bonded to the acousto-optic crystal. An incident light beam 2 enters the acousto-optic crystal 26 at Bragg angle to generate a zero-order diffraction light beam 4 and a first-order diffraction light beam 6.

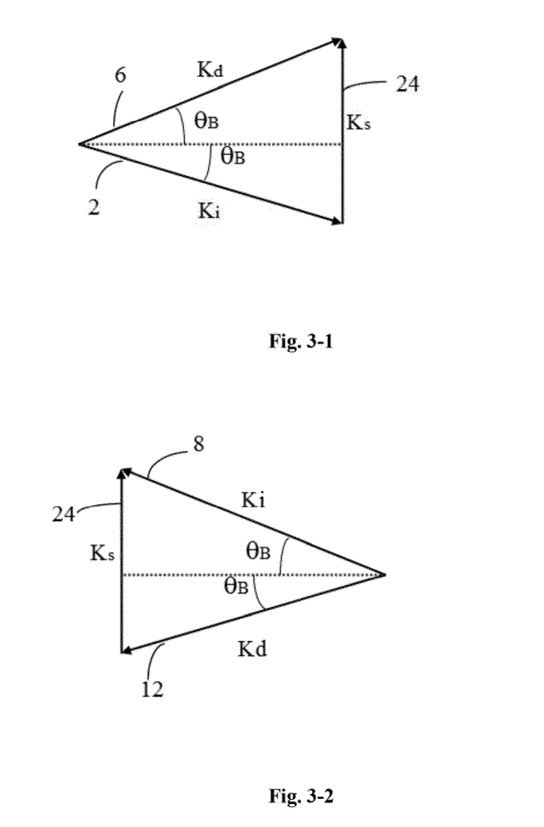

The principle of the acousto-optic filter is based upon a phenomenon known as Bragg diffraction that involves the interaction process of photons (light energy's quanta) and phonons (acoustic energy's quanta). Both energy and momentum are conserved in this interaction process. κ_{d}=κᵢ+κₛ is required in momentum conservation, wherein κ_{d} is the momentum of diffraction photon, κᵢ is the momentum of incident photon and κₛ is the momentum of interactive phonon. The formula below is obtained after is removed: κ_{d}=κᵢ+κₛ, which is the fundamental wave vector equation in Bragg diffraction and means that diffracted light wave vector is the vector sum of the incident light wave vector and the acoustic wave vector, as shown in FIG. 3-1. The relation of (ω_{f}=ω+Ω) is required in energy conservation, wherein ωᵣ is the angular frequency of diffraction light, ω is the angular frequency of incident light and Ω is the angular frequency of acoustic wave. The formula below is obtained after is removed: ωᵣ=ω+Ω. This means that the angular frequency of diffraction photon is slightly altered by the angular frequency of acoustic wave, or so called Doppler frequency shift. Acousto-optic Tunable Filter (AOTF) 100 is a solid-state bandpass optical filter that can be tuned by electric signal. Compared with the traditional techniques, AOTF provides continuous and fast tuning capability with narrow spectrum bandwidth. Acousto-optic filters can be divided in two categories: collinear and non-collinear. Narrow-band filtering can be realized by a non-collinear and far off-axis type fitter. From the formula ωᵣ=ω+Ω, it is known that the magnitude of the frequency shift of light wave is equal to the frequency of acoustic wave.

While Doppler frequency shift in AOTF is small because acoustic wave frequency is of many orders of magnitude smaller compared with the light wave frequency, unstable operation can still arise in some laser systems. A solution to this problem is the use of two AOTFs in which the second AOTF is used for offsetting the frequency shift caused by the first AOTF. Another solution is the use of two transducers on a single acousto-optic crystal. But these solutions have a few shortcomings such as: 1), the increase of system size and electric power consumption, 2), more difficult for optical alignment, 3), unstable operation, and 4), cost increase, which is especially important for mass production.

FIG. 2 illustrates a tunable acousto-optic filter 200 capable of eliminating frequency shift effectively. The tunable acousto-optic filter 200 comprises a transducer 22, an acousto-optic crystal 26, a radio frequency signal source 20 and a total reflection mirror 28, an incident light beam 2 enters the acousto-optic crystal 26 at Bragg angle to generate a zero-order diffracted light beam 4 and a first-order diffracted light beam 6, which is diffracted again by acousto-optic crystal 26 into a zero-order diffracted light beam 10 and a first-order diffracted light beam 12 after being reflected by the total reflection mirror 28. FIG. 3-1 and FIG. 3-2 illustrate the wave vector relation among incident light (κᵢ), diffraction light (κ_{d}) and acoustic wave (κₛ). As mentioned above, the relation κᵢ+κₛ=κ_{d} is always true, whether plus sign (+) or minus sign (−) is used is determined by the direction of incident acoustic wave with respect to that of the acoustic waves. In FIG. 3-1, light 2 (κ₂), light 6 (κₛ) and acoustic wave 24 (κₛ) have such a relation that: κ₂+κₛ=κ₄. The acoustic wave κₛ leads to not only upward shift of the diffracted light, but also upward shift of the angular frequency ω of the light by Ω=νₛ|κₛ|, wherein νₛ is the velocity of acoustic wave. In FIG. 3-2, light 8 (κ₈), light 12 (κ₁₂) and acoustic wave 24 (Kₛ) have such a relation that: κ₅−κₛ=κ₁₂. In this case, acoustic wave leads to downward shift and also downward shift of the angular frequency ω of the light 12 diffracted by νₛ|κₛ|. The upward and downward shifts are basically the same, so the overall frequency shift is fully eliminated when the light 12 exits from the acousto-optic filter 200.

In some embodiments, for example, when narrow-band tuning is needed, an anisotropic and birefringent acousto-optic crystal is used. One of the crystals is tellurium dioxide (TeO₂), which is widely used in such applications because it has high optical uniformity, low light absorbance and high damage threshold to optical power when operating under a shear mode. Other crystals such as lithium niobate (LiNbO₃), gallium phosphide (GaP) and lead molybdate (PbMoO₄) are also frequently used in a variety of acousto-optic sources. There are several factors that influence the choice of a particular crystal such as the type of acousto-optic source, whether high-quality crystal is easily available and the requirements of a particular application, such as diffraction efficiency, power loss, degree of dispersion of the incident light and the diffracted light and overall source size, etc.

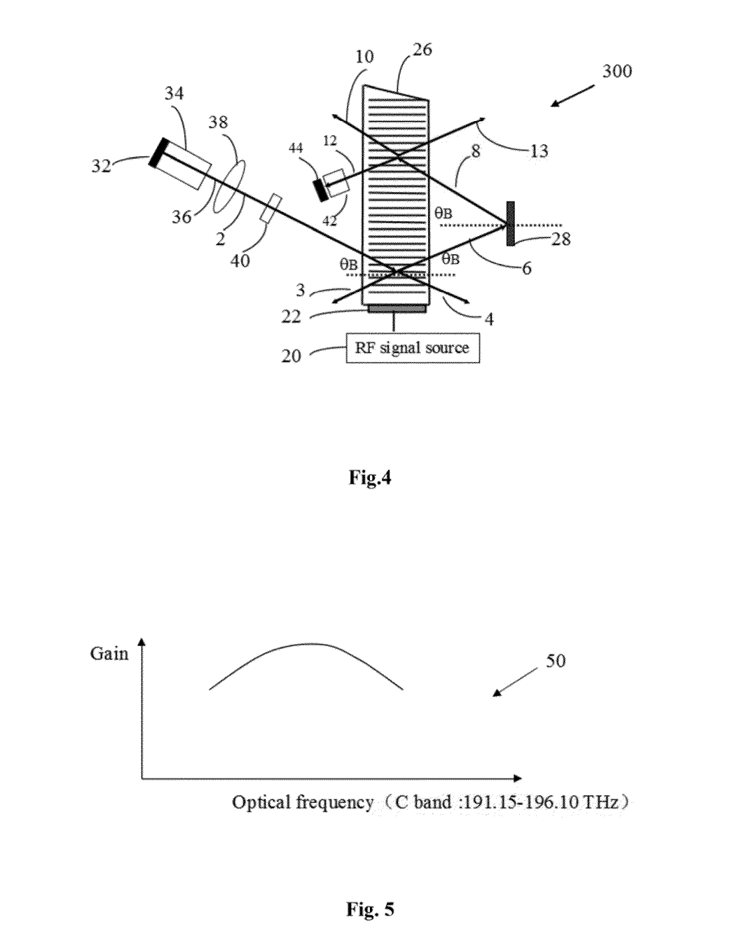

FIG. 4 illustrates an external cavity tunable laser 300 using a tunable acousto-optic filter as shown in FIG. 2 and a single etalon. The tunable laser 300 comprises a laser cavity end mirror 32 directly plated on a laser gain medium 34, the laser gain medium 34, an intracavity collimating lens 36, an active optical phase modulator 40, a tunable acousto-optic filter 100, an intracavity total reflection mirror 28, an etalon 42 and a total reflection mirror 44, wherein the laser cavity end mirror 32 and the total reflection mirror 44 form a laser resonant cavity.

Laser output mirror differs in reflectivity for light with different frequencies or colors, and the reflectivity mentioned herein means a reflectivity corresponding to the frequency bandwidth of an operating laser. The laser cavity end mirror 32 can be either a partial reflection mirror or a total reflection mirror according to different situations. When the laser gain medium is a semiconductor gain medium that has a relatively large output divergent angle, the intracavity collimating lens of the tunable laser 300 is normally used. When the laser gain medium is gas, liquid or some solid media, the intracavity collimating lens is not often used, instead, a non-planar cavity mirror is used to realize a reasonable distribution of intracavity light beams. When such lasers are used for fiber optical communication, an output light beam 4 needs to be coupled to an optical fiber, so the collimating lens 38 is indispensable.

In the tunable laser 300, a wideband light beam 36 emitted from the laser gain medium 34 is collimated by the intracavity collimating lens 38 to form a light beam 2, the light beam 2 enters the acousto-optic crystal 26 at Bragg angle in the opposite direction of the acoustic waves inside the acousto-optic crystal 26 through the active optical phase modulator 40, a first-order diffracted light beam 6 enters the intracavity total reflection mirror 28 at Bragg angle which has an optical reflection surface aligned parallel to the propagation direction of the acoustic wave inside the acousto-optic crystal 26, and the reflected light beam 8 by the total reflection mirror 28 enters the acousto-optic crystal 26 at Bragg angle. A first-order diffracted light beam 12 of the second diffraction by the acousto-optic crystal 26 passes through the etalon 42 and is then reflected back into a laser cavity by the total reflection mirror 44, thus creating laser oscillation and amplification inside the laser cavity. During this process, light beams 4 and 10 are the zero-order diffracted light beams of the light beams 2 and 8 respectively inside the laser cavity; a light beam 13 is the zero-order diffracted light beam of the light beam 12, which leaks out of the laser cavity and becomes the loss of the laser cavity. The light beam 4 is selected as a laser output light beam due to its higher power compared with other light beams and zero optical frequency shifts. Light beams 10 and 13 can be used for monitoring the optical power and frequency inside the laser cavity.

As previously analyzed, optical wavelength shifts generated by the first diffraction and the second diffraction are just opposite to each other, so the overall optical wavelength shift caused by the tunable acousto-optic filter 26 in the tunable laser 300 is zero. Narrower band laser oscillation occurs due to two diffractions by the tunable acousto-optic filter 26. The etalon 42 that is inserted into the laser cavity is used for further compressing the bandwidth of laser output and regulating the optical frequency interval of output light to be consistent with its free spectrum range (FSR). For applications in fiber optical communication, for example, the etalon 42 may have a free spectrum range of 100 GHz, 50 GHz or 25 GHz and high finesse to increase the side mode suppression ratio and narrow band output. FIG. 7 illustrates the tunable laser 300 output spectrum, which is conventionally used in fiber optical communication within C band or L band spectrum and 50 GHz frequency interval.

Laser output tuning is realized via the active optical phase modulator 41 and the tunable acousto-optic filter 26. The light wave resonant frequency in the laser cavity can be changed by changing the RF frequency of the radio frequency signal source of the tunable acousto-optic filter 26. In accordance with different light wave resonant frequencies, the active optical phase modulator 41 enables a particular light wave to form laser oscillation and amplification in the laser cavity by regulating the phase of the light wave.

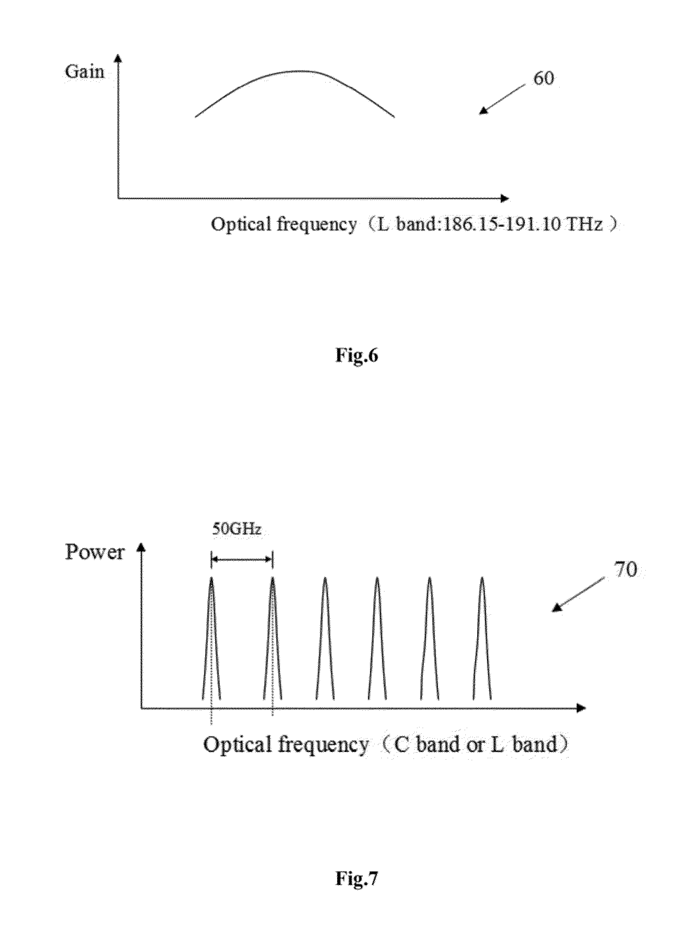

The spectrum bandwidth of a single laser gain medium is limited, for example, a semiconductor gain medium used in industry has an effective gain bandwidth usually less than 6 THz. Therefore, the tunable spectrum range of the laser 300 using such gain medium is also limited to about 6 THz. It is desirable for many tunable laser applications that the output spectrum range of the tunable laser can be expanded. For example, the range of C band and L band conventionally used in fiber optical communication is about 10 THz, as shown in FIG. 5 and FIG. 6. To achieve such a bandwidth, the use of a single laser gain medium for a tunable laser is not enough.

Detailed description is made below to the external cavity tunable laser of the invention.

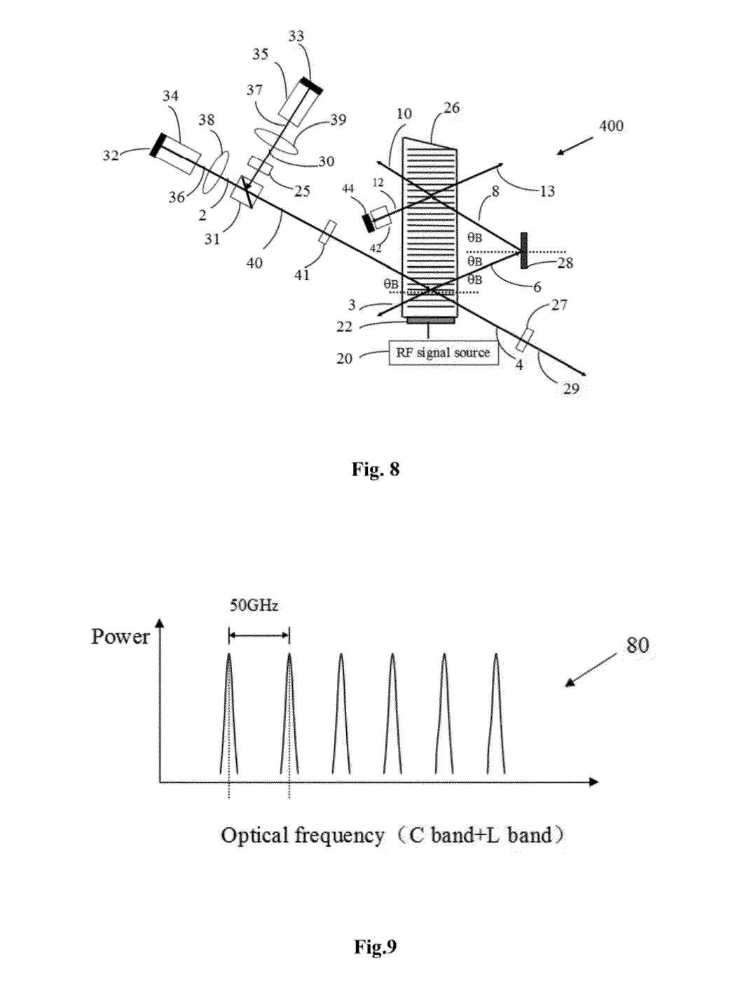

Provided in the invention is a method for solving the above problems, in which two laser gain media are coupled together by a passive polarization rotator and a light polarization combiner. As shown in FIG. 8, the external cavity wideband tunable laser 400 comprises a first laser gain medium 34, a laser cavity end mirror 32 directly plated on the first laser gain medium 34, a first intracavity collimating lens 38, a second laser gain medium 35, a second laser cavity end mirror 33 directly plated on the second laser gain medium 35, a second intracavity collimating lens 39, a passive polarization rotator 25, a light polarization combiner 31, an active optical phase modulator 41, a tunable acousto-optic filter 26, an intracavity reflection mirror 28, an etalon 42, a laser cavity total reflection mirror 44, an active polarization rotator 27 and a laser drive control circuit. The passive polarization rotator 25 is arranged behind the second intracavity collimating lens 39; the second laser gain medium 35, the second intracavity collimating lens 39 and the passive polarization rotator 25 are vertical to the first laser gain medium 34 and the first intracavity collimating lens 38: the light polarization combiner 31 is arranged behind the first intracavity collimating lens 38 and the passive polarization rotator 25, and forms an angle of 45 degrees with respect to the output light beams of the first intracavity collimating lens 38 and the passive polarization rotator 25, and is used for coupling the light beam of the first laser gain medium 34 and the light beam output from the passive polarization rotator 25; the active polarization rotator 27 is arranged on the light path 4 of the output light beam of the laser and used for rotating the polarization state of the output light beam of the passive polarization rotator 25 by 90 degrees so that the polarization state of the output light beam from the second laser gain medium is the same as that of the output light beam of the first laser gain medium 34; The etalon 42 and the total reflection mirror 44 are arranged on the opposite side of the tunable acousto-optic filter from the intracavity reflection mirror. The tunable laser 400 of the invention and the tunable laser 300 have the same fundamental working principle. The difference between them is that the tunable laser 400 comprises two laser gain media with different spectrum ranges and two laser sub-cavities. The first laser sub-cavity is formed by the first laser cavity end mirror 32 and the total reflection mirror 44, and the second laser sub-cavity is formed the second laser cavity end mirror 33 and the total reflection mirror 44.

In the preferred embodiment, the gain spectra of the first laser gain medium 34 and the second laser gain medium 35 are in C spectral band and L spectral band respectively, the first laser cavity end mirror 32 may be a total reflection mirror or a partial reflection mirror within the C spectral band range, and the second laser cavity end mirror 33 may be a total reflection mirror or a partial reflection mirror within the L spectral band range. The intracavity reflection mirror 28 and the total reflection mirror 44 each have a reflectivity equal to or approximate to 100% at least within the spectrum range of the C spectral band and the L spectral band, and each are one of the following types of reflection mirrors: plane mirror, convex mirror and concave mirror. The spectrum range of the etalon 42 is more than or equal to a spectral band ranging from 186.15 THz to 196.10 THz, and has free spectrum range of 50 GHz and a high finesse; the spectrum range of the active optical phase modulator 41 is more than or equal to a spectral band ranging from 186.15 THz to 196.10 THz; the spectrum range of the passive polarization rotator 25 is more than or equal to a spectral band ranging from 186.15 THz to 196.10 THz; and the spectrum range of the active polarization rotator 41 is more than or equal to a spectral band ranging from 186.15 THz to 196.10 THz. The active polarization rotator 41 is one of the following types: electro-optic rotator, or magneto-optic rotator, or liquid crystal rotator, or acousto-optic rotator, or the polarization rotators based on other forms of physical optical effect, or a combination of the aforementioned rotators, and the active polarization rotator has a spectrum range equal to or more than 186.15 THz-196.10 THz. The active optical phase modulator 41 is one of the following types: electro-optic phase modulator, or magneto-optic phase modulator, or liquid crystal phase modulator, or acousto-optic phase modulator, or phase modulators based on other forms of physical optical effect, or a combination of the aforementioned phase modulators, and the active optical phase modulator 41 has a spectrum range equal to or more than 186.15 THz-196.10 THz. The tunable acousto-optic filter 26 is a narrow band optical filter and has a spectrum range equal to or more than a spectral band ranging from 186.15 THz to 196.10 THz, and the FWHM of the filter spectrum of the tunable acousto-optic filter is not more than twice the free spectrum range of the etalon 42. The tunable acousto-optic filter 26 comprises an acousto-optic crystal 26 and an acoustic wave transducer 22 adhered to the acousto-optic crystal 26, and the material of the acousto-optic crystal 26 is TeO₂.

FIG. 5 shows the gain curve of the first laser gain medium 34, and the spectrum range is from 191.15 THz to 196.10 THz. FIG. 6 shows the gain curve of the second laser gain medium 35, and the spectrum range is from 186.15 THz to 191.10 THz.

A light beam emitted from the second laser gain medium 35 is collimated by the second intracavity collimating lens 39 and then passes through the passive polarization rotator 25, which rotates the polarization state of the light beam by 90 degrees, and finally, the light beam is coupled into the laser cavity by the polarization beam combiner 31. Therefore, the laser cavity end mirror 32 and the total reflection mirror 44 form the first laser sub-cavity in C spectral band; the laser cavity end mirror 33 and the total reflection mirror 44 form the second laser sub-cavity in L spectral band. The first and second laser sub-cavities are both tuned by adjusting the active optical phase modulator 41 and changing the RF frequency of the radio frequency signal source 20. The laser output from both laser sub-cavities as the light beam 4.

The polarization direction of the laser output generated by the second laser resonant sub-cavity in L spectral band is vertical to that of the laser output generated by the first laser resonant sub-cavity in C spectral band, in order to keep the same polarization states of the laser output from two laser sub-cavities. The polarization state of the laser 400 is rotated by the active polarization rotator 27 by 90 degrees when the laser output is from the second sub-cavity in L spectral band.

The light beam coupling by the polarization beam combiner 31 in the external cavity wideband tunable laser 400 is based on such an assumption that fluorescent light emitted by the first gain medium 34 and the second gain medium 35 is linearly polarized light. Fluorescent light emitted by a conventional semiconductor gain medium is usually linearly polarized light. If the light emitted by the laser gain media is non-polarized light, a polarizer behind the first intracavity collimating lenses 38 and 39 will be needed. In practice, the spectra of these two laser gain media will overlap partially. The overlapped light is likely to generate oscillation to further form output in the two laser sub-cavities. This must be avoided in some applications. One of the solutions to solve this problem is to make some adjustments to the length of the two laser sub-cavities so that for a particular optical frequency, oscillation output can only be formed in one laser sub-cavity. Another solution is to use a polarizer on the output light path of the active polarization rotator 27. Because the polarization states of the output light beams in the two laser sub-cavities are vertical to each other, one of the output light beams can be stopped.

In tunable lasers with 100 GHz, 50 GHz and 25 GHz optical frequency intervals for fiber optical communication, the optical frequency intervals between the last channel of C spectral band in a long wave direction and the first channel of L spectral band in a short wave direction are 100 GHz, 50 Ghz and 25 GHz respectively. Therefore, tunable output with 100 GHz optical frequency interval, the spectrum of which covers C and L spectral bands, can be achieved without addition of other devices to the laser 400. If the laser gain media of in C and L spectral bands are coupled by a thin film optical filter for example, the difficulty to avoid such problem will be increased dramatically.

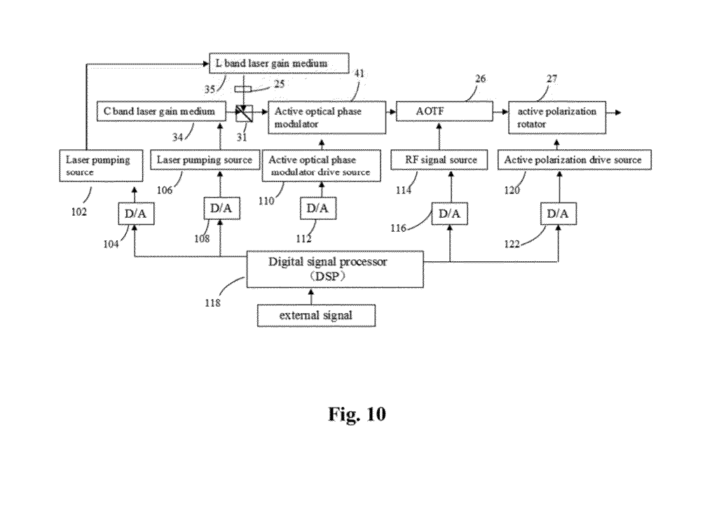

FIG. 10 shows the laser control circuit system of the external cavity wideband tunable laser 400. The laser control circuit system comprises a digital signal processor (DSP) 118 with embedded software programs, five digital-to-analog conversion (D/A) modules 104, 108, 112, 116 and 122. The digital signal processor (DSP) 118 with embedded software programs is used for controlling the first laser pumping source 102, the second laser pumping source 106, the active optical phase modulator drive source 110, the radio frequency signal source 114 and the active polarization rotator drive source 120 through the digital-to-analog conversion (D/A) modules 104, 108, 112, 116 and 122 respectively. The digital signal processor 118 may also receive an external instruction to control the tunable laser 400.

The above description is for demonstration and description only, not a detailed one without omission, and is not intended to limit the invention within the described specific forms. With the aforementioned description, many modifications and variations to the invention are possible. The chosen embodiments are merely for better explanation of the principle and practical applications of the invention. This description enables people familiar with this art to make better use of the invention, and to design different embodiments based on the actual needs and implement corresponding modifications.

What is claimed is:

1. An external cavity wideband tunable laser with dual laser gain media coupled by a polarization beam combiner comprising: a first laser gain medium, a first laser cavity end mirror arranged on the first laser gain medium, a first intracavity collimating lens for collimating the light beam emitted from the first laser gain medium, an active optical phase modulator, a tunable acousto-optic filter, an intracavity reflection mirror, which are all arranged sequentially, an etalon and a total reflection mirror, which are arranged on the opposite side of the tunable acousto-optic filter from the intracavity reflection mirror, the laser further comprises:
a second laser gain medium, a second laser cavity end mirror arranged on the second laser gain medium, a second intracavity collimating lens for collimating the light beam emitted from the second laser gain medium, the optical axes of second laser gain medium and the second intracavity collimating lens arranged in vertical direction to the optical axes of the first laser gain medium and the first intracavity collimating lens;
a passive polarization rotator arranged behind the first intracavity collimating lens to rotate the polarization direction by 90 degrees of the light beam outputted from the first intracavity collimating lens, and a polarization beam combiner aligned with an angle of 45 degrees with respect to the output light beams of the first intracavity collimating lens and the passive polarization rotator to pass the light beam from the first intracavity collimating lens and to reflect the light beam from the second intracavity collimating lens;
an active polarization rotator arranged on the output light path of the laser and used for rotating the polarization state of the output light beam from the second laser gain medium by 90 degrees so that the polarization state of the output light beam is the same as that of the output light beam from the first laser gain medium:
a radio frequency signal source for providing radio frequency energy for the tunable acousto-optic filter and for adjusting the oscillation wavelength of the laser resonant cavity by changing RF frequency; and
pumping sources for the two laser gain media, an active optical phase modulator drive source, an active polarization rotator drive source and a laser drive control circuit.

2. The external cavity wideband tunable laser with dual laser gain media coupled by a polarization beam combiner of claim 1, wherein the gain spectra of the first laser gain medium and the second laser gain medium are C band and L band respectively.

3. The external cavity wideband tunable laser with dual laser gain media coupled by a polarization beam combiner of claim 1, wherein the first laser cavity end mirror is a total reflection mirror or a partial reflection mirror within the C band range, and the second laser cavity end mirror is a total reflection mirror or a partial reflection mirror within the L band range.

4. The external cavity wideband tunable laser with dual laser gain media coupled by a polarization beam combiner of claim 2, wherein the first laser cavity end mirror is a total reflection mirror or a partial reflection mirror within the C band range, and the second laser cavity end mirror is a total reflection mirror or a partial reflection mirror within the L band range.

5. The external cavity wideband tunable laser with dual laser gain media coupled by a polarization beam combiner of claim 1, wherein the intracavity total reflection mirror has approximately 100% reflectivity within the C band and the L band, and is one of the following types of reflective mirrors: plane mirror, convex mirror and concave mirror.

6. The external cavity wideband tunable laser with dual laser gain media coupled by a polarization beam combiner of claim 2, wherein the intracavity total reflection mirror has approximately 100% reflectivity within the C band and the L band, and is one of the following types of reflective mirrors: plane mirror, convex mirror and concave mirror.

7. The external cavity wideband tunable laser with dual laser gain media coupled by a polarization beam combiner of claim 1, wherein the spectrum range of the etalon is more than or equal to a spectral band ranging from 186.15 THz to 196.10 THz, and the etalon has a free spectrum range of 50 GHz and high finesse; the spectrum range of the active optical phase modulator is more than or equal to a spectral band ranging from 186.15 THz to 196.10 THz.

8. The external cavity wideband tunable laser with dual laser gain media coupled by a polarization beam combiner of claim 2, wherein the spectrum range of the etalon is more than or equal to a spectral band ranging from 186.15 THz to 196.10 THz, and the etalon has a free spectrum range of 50 GHz and high finesse; the spectrum range of the active optical phase modulator is more than or equal to a spectral band ranging from 186.15 THz to 196.10 THz.

9. The external cavity wideband tunable laser with dual laser gain media coupled by a polarization beam combiner of claim 1, wherein the active polarization rotator is one of the following types: electro-optic rotator, or magneto-optic rotator, or liquid crystal rotator, or acousto-optic rotator, or rotators based on other forms of physical optical effect, or a combination of the aforementioned rotators, and the active light rotator has a spectrum range equal to or more than 186.15 THz-196.10 THz.

10. The external cavity wideband tunable laser with dual laser gain media coupled by a polarization beam combiner of claim 2, wherein the active polarization rotator is one of the following types: electro-optic rotator, or magneto-optic rotator, or liquid crystal rotator, or acousto-optic rotator, or rotators based on other forms of physical optical effect, or a combination of the aforementioned rotators, and the active light rotator has a spectrum range equal to or more than 186.15 THz-196.10 THz.

11. The external cavity wideband tunable laser with dual laser gain media coupled by a polarization beam combiner of claim 1, wherein the tunable acousto-optic filter is a narrow band optical filter and has a spectrum range equal to or more than a spectral band ranging from 186.15 THz to 196.10 THz, and the FWHM of the filter spectrum of the tunable acousto-optic filter is not more than twice the free spectrum range of the etalon.

12. The external cavity wideband tunable laser with dual laser gain media coupled by a polarization beam combiner of claim 2, wherein the tunable acousto-optic filter is a narrow band optical filter and has a spectrum range equal to or more than a spectral band ranging from 186.15 THz to 196.10 THz, and the FWHM of the filter spectrum of the tunable acousto-optic filter is not more than twice the free spectrum range of the etalon.

13. The external cavity wideband tunable laser with dual laser gain media coupled by a polarization beam combiner of claim 1, wherein the tunable acousto-optic filter comprises an acousto-optic crystal and an acoustic wave transducer bonded to the acousto-optic crystal, and the acousto-optic crystal is TeO₂.

14. The external cavity wideband tunable laser with dual laser gain media coupled by a polarization beam combiner of claim 2, wherein the tunable acousto-optic filter comprises an acousto-optic crystal and an acoustic wave transducer bonded to the acousto-optic crystal, and the acousto-optic crystal is TeO₂.

15. The external cavity wideband tunable laser with dual laser gain media coupled by a polarization beam combiner of claim 1, wherein the active optical phase modulator is one of the following types: electro-optic phase modulator, or magneto-optic phase modulator, or liquid crystal phase modulator, or acousto-optic phase modulator, or phase modulators based on other forms of physical optical effect, or a combination of the aforementioned phase modulators, and the active optical phase modulator has a spectrum range equal to or more than 186.15 THz-196.10 THz.

16. The external cavity wideband tunable laser with dual laser gain media coupled by a polarization beam combiner of claim 2, wherein the active optical phase modulator is one of the following types: electro-optic phase modulator, or magneto-optic phase modulator, or liquid crystal phase modulator, or acousto-optic phase modulator, or phase modulators based on other forms of physical optical effect, or a combination of the aforementioned phase modulators, and the active optical phase modulator has a spectrum range equal to or more than 186.15 THz-196.10 THz.

17. The external cavity wideband tunable laser with dual laser gain media coupled by a polarization beam combiner of claim 1, wherein the laser drive control circuit comprises a digital signal processor, five digital-to-analog conversion modules, and the digital signal processor is used for controlling the first and second laser pumping sources, the active optical phase modulator drive source, the radio frequency signal source and the active polarization rotator drive source respectively through the five digital-to-analog conversion modules.
